(19) United States
(12) Patent Application Publication
(10) Pub. No.: US 2002/0070806 A1
(43) Pub. Date: Jun. 13, 2002

(54) ASYMMETRIC TRAPEZOIDAL GATE MOSFET AND RF AMPLIFIER USING SAME

(76) Inventors: SHYH-CHYI WONG, TAICHUNG (TW); CHI-HUNG KAO, TAIPEI (TW)

Correspondence Address: FINNEGAN, HENDERSON, FARABOW, GARRETT &, DUNNER LLP, 1300 I STREET, NW, WASHINGTON, DC, 20005, US

(21) Appl. No.: 09/342,903

(22) Filed: Jun. 30, 1999

(51) Int. Cl. H03F 3/16

(52) U.S. Cl. 330/277

(57) ABSTRACT

An ATG MOSFET is constructed of a plurality of ATG MOSFET elements each including a gate region. One of a source and drain region of each ATG MOSFET element is shared in common with an adjacent one of the ATG MOSFET elements. The plurality of ATG MOSFET elements are connected in parallel to provide a desired driving current capacity and reduced effective driving capacitance. The ATG MOSFET is implemented in a high frequency RF amplifier.

### BACKGROUND OF THE INVENTION

1. Field of Invention

The present invention relates to a MOSFET having a structure providing a reduced device capacitance and, more particularly, to the structure of such of MOSFET and its implementation in circuitry.

2. Description of the Related Art

In a conventional MOSFET gate structure, major parasitic effects arise as a result of Miller effect capacitance and an internal capacitance which originates at the drain-side junction of the MOSFET. Small signal analysis of the MOSFET device reveals that the Miller effect capacitance works as a multiplication factor with the gate-drain capacitance to create an effectively large capacitance acting on the MOSFET device. This effectively large capacitance causes major parasitic capacitance effects which degrade device performance. For example, such capacitance causes junction current leakage which, in turn, causes increased standby power or signal loss. It is therefore desirable to reduce the Miller effect capacitance or the gate-drain capacitance, in order to reduce such parasitic effects.

One way to accomplish this is to reduce the drain junction width. By doing so, the gate- drain capacitance value is reduced. Due to the multiplicative nature that the Miller effect has on the gate-drain capacitance value, reducing the gate-drain capacitance reduces the effective capacitance value and in turn the parasitic effects in the MOSFET device. Therefore, as the parasitic effects are reduced, a higher MOSFET gain can be achieved. Additionally, high frequency bandwidth performance of the MOSFET device is significantly reduced by drain-side parasitic junction capacitance and the Miller effect capacitance.

An asymmetric trapezoidal gate (ATG) MOSFET is a device in which the gate has a relatively small drain-side width as compared to the source-side width, giving it a trapezoidal shape. The reduced drain junction area, in turn, reduces the Miller capacitance.

P. Grignoux et al. “Modeling of MOSFET Transistor with non-rectangular-gate Geometries,” disclose a model for MOSFETs with gates of arbitrary shape, but ignore second order effects such as body effect and channel length modulation. In addition, Grignoux et al. fail to address frequency bandwidth effects of ATG transistors.

T. H. Kuo et al., “Mismatch and Asymmetric Characteristic of Concentric MOSFETs” disclose asymmetrical properties of concentric transistors including offset voltages and current mismatch. Kuo et al. fail to address frequency bandwidth effects of such transistors.

A. El-Hennaway et al., “Modeling and Characterization of TG-MOSFET”, disclose a model of a short channel trapezoidal-formed gate MOS field effect transistor (TG-MOSFET). El-Hennaway provide simulation results and modeling analysis but fails to discuss any frequency bandwidth effects resulting from the TG-MOSFET structure.

While basic structure and characteristics of non-rectangular gate MOSFETs have been considered, specific applications of such devices have not been adequately investigated in areas such as, for example, high frequency signal applications.

### SUMMARY OF THE INVENTION

Accordingly, the present invention is directed to a novel asymmetrical trapezoidal gate (ATG) MOSFET structure for preventing or reducing parasitic effects and its use in circuitry, which substantially obviates one or more of the problems due to the limitations and disadvantages of the related art. Additional features and advantages of the invention will be set forth in part in the description which follows, and in part will be apparent from the description, or may be learned by practice of the invention. The objectives and other advantages of the invention will be realized and attained by means of the elements and combinations particularly pointed out in the appended claims.

To achieve these and other advantages and in accordance with the purpose of the invention, as embodied and broadly described herein, an RF amplifier is provided comprising a MOSFET as an amplifier element, where said MOSFET is constructed as an ATG MOSFET.

Also in accordance with the present invention there is provided an ATG MOSFET comprising a plurality of ATG MOSFET elements each including a gate region, one of a source region and drain region of each ATG MOSFET element being shared in common with an adjacent one of the ATG MOSFET elements. The ATG MOSFET elements are connected in parallel. Further, in each ATG MOSFET element the gate region tapers at an approximately 45° angle relative to the drain region.

It is to be understood that both the foregoing general description and the following detailed description are exemplary and explanatory only and are not restrictive of the invention, as claimed.

### BRIEF DESCRIPTION OF THE DRAWINGS

Other features and advantages of the present invention will become apparent in the following detailed description of the preferred embodiment, with reference to the accompanying drawings, of which:

FIG. 1a depicts a circuit diagram of a single RF Low Noise Amplifier (LNA).

FIG. 1b depicts a circuit diagram of a cascade RF LNA.

FIG. 1c depicts a frequency response equivalent MOSFET amplifier circuit diagram.

FIG. 2a depicts a frequency response equivalent MOSFET amplifier circuit diagram of the gate-drain junction capacitance.

FIG. 2b depicts a frequency response equivalent MOSFET amplifier circuit diagram of a gate-drain junction capacitance modeled to include Miller effect capacitance.

FIG. 3 depicts an ATG MOSFET device layout.

FIG. 4a depicts a multiple finger ATG MOSFET device layout.

FIG. 4b depicts a circuit diagram of the multiple finger ATG MOSFET device layout provided in FIG. 4a.

FIG. 5 depicts a graph of performance of a single device design LNA.

FIGS. 6a and 6b depict graphs of unity-power-frequency gain and carrier wave frequency of a single device ATG MOSFET and symmetric gate MOSFET design LNA.

FIGS. 7a and 7b depict graphs of unity-power-frequency gain and carrier wave frequency of a cascade device ATG MOSFET and symmetric gate MOSFET design LNA.

### DETAILED DESCRIPTION OF THE PREFERRED EMBODIMENTS

According to the present invention, an RF amplifier constructed to include one or more ATG MOSFETs are provided to reduce the parasitic effects associated with drain-side junction and Miller effect capacitance.

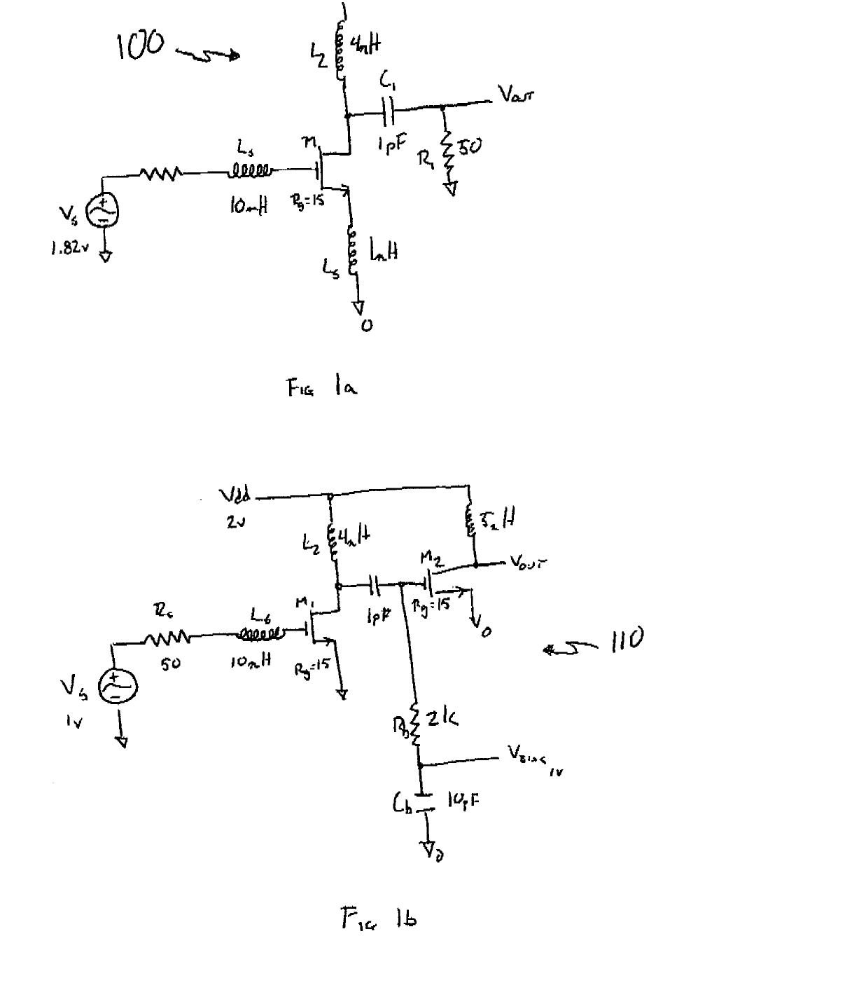

FIG. 1a depicts a circuit diagram of a high frequency single RF Low Noise Amplifier (LNA) 100 which utilizes a MOSFET transistor M1. FIG. 1b depicts a circuit diagram of a high frequency cascade RF LNA 110, which utilizes two cascaded MOSFET transistors M1 and M2. When calculating the small signal operation of the MOSFET amplifier circuits of FIG. 1a or 1b, the equivalent circuit of the MOSFET can be represented by FIG. 1c, wherein the source, drain and gate terminals are designated S, D, and G, respectively. The capacitances between the gate and drain, drain and source, and gate and source are represented by C_{GD}, C_{DS}, and C_{GS}, respectively. The voltage across C_{GS} is V_{GS} and the equivalent circuit includes a current source gmV_{GS}, where gm is a transconductance value of the MOSFET device, as well as a finite output resistance r_{O} of the MOSFET in the pinch-off region. Typically, C_{GD}, C_{DS}, and C_{GS} are quite small, usually in the range of 1 to 3 pF. However, according to Miller's theorem the magnitude of C_{GD} is multiplied by a large number, and effectively appears in parallel with C_{GS}. This multiplication of C_{GD} is known as the Miller effect. The resulting large input capacitance represented by the parallel combination of C_{GD} and C_{GS} together with the resistance of the input signal source, form a low pass filter that limits high-frequency response. Capacitance C_{DS} appears in parallel with the load impedance, again forming a low-pass filter. As a result, the three capacitances C_{GD}, C_{DS}, and C_{GS} cause the amplifier gain to drop at the high-frequency end of the spectrum. At low and midband frequencies, these capacitances have very high reactances and a greatly reduced effect.

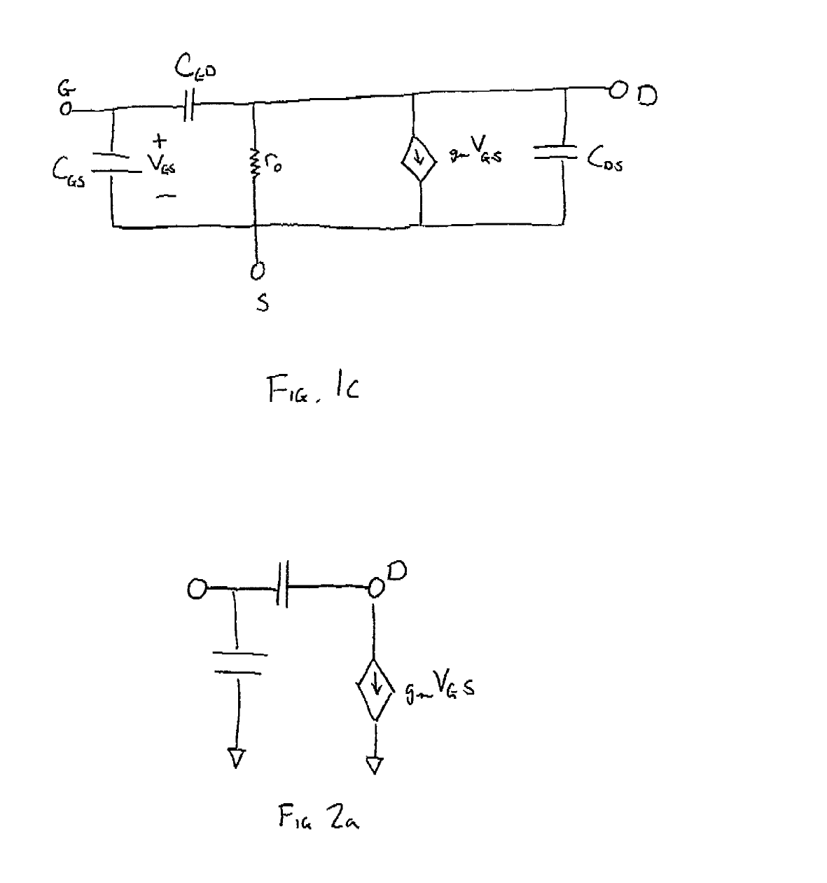

FIG. 2a illustrates an equivalent circuit for analyzing the MOSFET amplifier in the high-frequency range. The equivalent amplifier circuit of FIG. 2a provides a gain of A. The amplifier circuit of FIG. 2a is reconfigured in FIG. 2b to illustrate the Miller effect capacitance C_{Miller}. Given that the voltages at the two ends of C_{GD} are in the ratio of the amplifier gain A, C_{GD} gives rise to a large effective capacitance, due to the Miller effect. The Miller effect capacitance as seen looking in from the gate is

C_{Miller}=(1+A)C_{GD} (1)

The Miller effect capacitance as seen looking in from the drain is

C″_{Miller}=(1+1/A)C_{GD} (2)

Assuming that C_{GD} is on the order of 1 to 3 pF, from equation (1) it is seen that as the gain A increases, the Miller effect capacitance C″_{Miller} is greatly increased. In equation (2) it is also seen that the Miller effect capacitance C″_{Miller} also exceeds C_{GD} as a function of gain A. The large capacitances caused by the Miller effect are detrimental to high speed and high frequency operation of the amplifier circuit. In order to increase circuit speed and amplifier bandwidth, while keeping the gain value constant, the Miller effect capacitance must be decreased. In order to decrease the Miller effect capacitance while keeping gain constant, C_{GD} must be decreased.

An embodiment consistent with the present invention provides a MOSFET with an ATG structure particularly adapted for use in RF amplifier circuits. By forming a MOSFET with reduced width of the channel which interfaces the drain terminal with the gate, the area of the gate-drain overlapping interface is reduced. Accordingly, C_{GD} is reduced as the area of the gate-drain interface is reduced. In accordance with equations (1) and (2), as C_{GD} is reduced, the Miller effect capacitance is reduced. With such a reduction in C_{GD}, and in turn C_{Miller}, increased speed and bandwidth may be achieved. Preferably, the drain width is formed such that it provides a C_{GD} in the range of 0.02 fF/μm to 0.5 fF/μm. Further, forming a drain region such that it provides a capacitance value below 0.35 fF/μm, lowers C_{GD} and provides proper drain current.

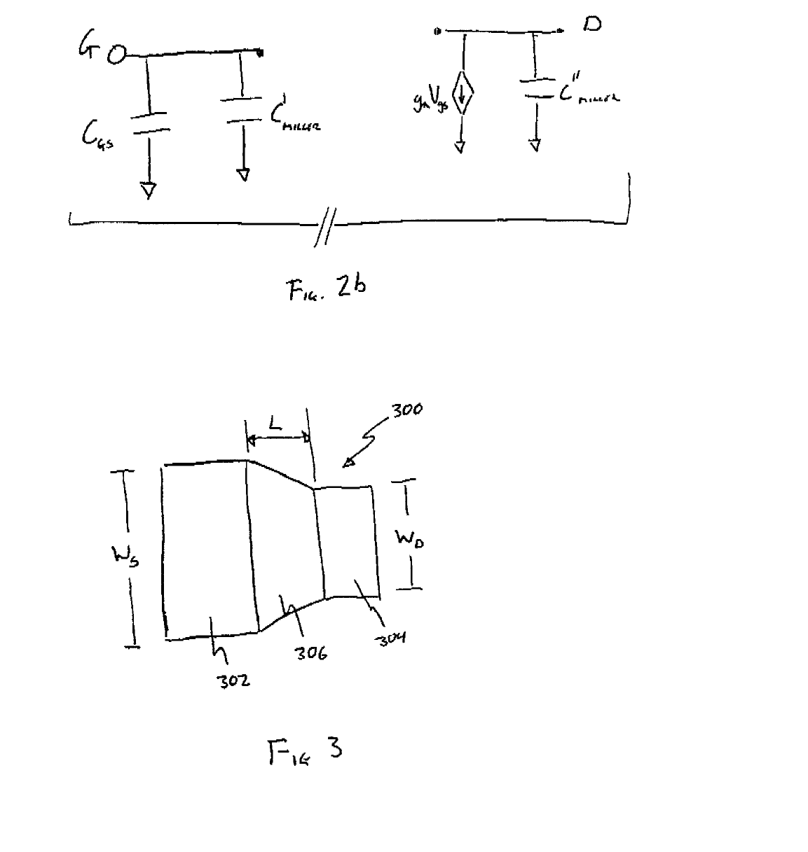

FIG. 3 diagrammatically illustrates a plan view of an ATG MOSFET 300 including a source region 302, a drain region 304, and a gate region 306. Also depicted are widths W_{S} and W_{D} of the source and drain regions, respectively, and a length L of gate region 306. In MOSFETs in general, including MOSFET 300, a maximum driving current (I_{DMAX}) the device can conduct is, in part, a function of the ratio W_{S}/L. In circuit applications that require each MOSFET to carry a large driving current, it is desirable to construct the MOSFET to have a large ratio W_{S}/L. One such application is in high frequency RF amplifier circuits such as circuits 100 and 110 illustrated in FIGS. 1a and 1b, respectively. Driving current may be on the order of several mA, but specific values depend on circuit parameters.

Particularly with respect to ATG MOSFET 300, however, increasing the ratio W_{S}/L also has the effects of increasing the width W_{D} and causing the ratio W_{S}/W_{D} to approach unity. These effects tend to negate the reduction in Miller effect capacitance that can otherwise be realized by use of an ATG MOSFET. The increased Miller effect capacitance in the ATG MOSFET constructed with a large ratio W_{S}/L will therefore detrimentally affect the operating speed and bandwidth of a RF amplifier circuit operating at a frequency over several hundred megahertz. Typically, commercial devices categorized as operating at high frequency operate at or above 900 MHz. For example, RF mobile products typically operate at frequencies of 900 MHz, 1.8 GHz or 2.4 GHz. Military application devices often operate at even higher frequency ranges.

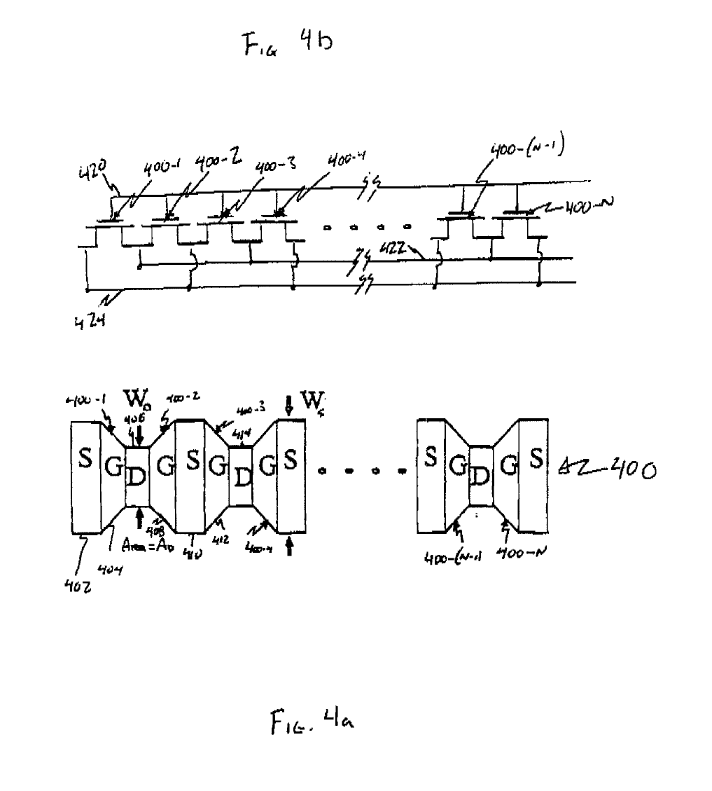

FIG. 4a diagrammatically illustrates a plan view of a multiple finger ATG MOSFET 400 suitable for use in a high frequency RF amplifier circuit. ATG MOSFET 400 is constructed of multiple ATG MOSFETs 400-1, 400-2, . . . , 400-N which in succession alternately share a common drain region or a common source region. For example, ATG MOSFET 400-1 consists of a source region 402, a gate region 404, and a drain region 406, while ATG MOSFET 400-2 shares with ATG MOSFET 400-1 the same drain region 406, and further includes a gate region 408 and source region 410. ATG MOSFET 400-3 shares with MOSFET 400-2 the same source region 410 and further includes a gate region 412 and a drain region 414.

FIG. 4b illustrates a circuit diagram of ATG MOSFET 400 and further shows additional wirings for connecting in parallel the multiple ATG MOSFETs 400-1, 400-2, . . . , 400-N that constitute ATG MOSFET 400. More particularly, wirings 420, 422, and 424 connect the gates, drains, and sources in parallel, respectively.

The structure of parallel connected ATG MOSFETs enables the individual ATG MOSFETs 400-1, 400-2, . . . , 400-N to each be constructed with a relatively small value of W_{D} and a suitable ratio W_{S}/W_{D} that are effective to provide a reduced Miller effect capacitance. On the other hand, the parallel connection of the respective ATG MOSFETs 400-1, 400-2, . . . , 400-N provides a driving current capacity that is substantially equal to the sum of their individual driving current capacities. As a result, a value of I_{DMAX} sufficient for use in a high frequency RF circuit is available.

Thus, the parallel connection of the multiple ATG MOSFETs provides an equivalent MOSFET with reduced Miller effect capacitance while also providing a large I_{DMAX}. However, the particular structure of ATG MOSFET 400 in which alternate source and drain regions are commonly shared between adjacent device enables a further reduction in the total device capacitance. The device capacitance of interest includes C_{Miller}, which is a multiple of C_{GD}, and a junction capacitance C_{J} between the drain region and the device substrate. As a result, two ATG MOSFETs connected in parallel (but not sharing a common diffusion region) would have a combined effective capacitance of:

2C_{Miller}+2C_{J} (3)

However, since in ATG MOSFET 400 alternate adjacent devices share a common drain region, the combined effective capacitance of those adjacent devices is:

2C_{Miller}+C_{J} (4)

As a result, the total capacitance of ATG MOSFET 400 is less than an equivalent set of discrete parallel connected devices.

An ATG MOSFET having characteristics suitable for any one of devices 400-1, 400-2, . . . , or 400-N is described in Cho et al., “An Analytic Current-Voltage and Capacitance-Voltage Model of the Asymmetric-Trapezoidal-Gate MOSFET”, Electron Device and Material Symposium, 1997, which is incorporated in its entirety herein by reference. In the device disclosed in Cho et al., the gate region tapers at an approximately 45° angle relative to the source region.

Structural features and DC characteristics of another ATG MOSFET suitable for any one of devices 400-1, 400-2, . . . , 400-N is described in Wong et al., “A DC Model for Asymmetric Trapezoidal Gate MOSFET's in Strong Inversion”, IEEE Transactions on Electron Devices, vol. 45, no.7, July 1998, which is incorporated in its entirety herein and by reference. Wong et al. discloses the benefits of the ATG MOSFET in terms of performance characteristics.

In constructing an exemplary ATG MOSFET 400 for use in a high frequency RF circuit, the total effective W_{S} of the device, i.e., the sum of the individual W_{S} values for the individual devices 400-1, 400-2, . . . , 400-N, should be at least 200 μm and possibly more depending on the I_{DMAX} requirement of the specific circuit application.

An ATG MOSFET can be fabricated in much the same way as a typical symmetrical gate MOSFET. In ATG MOSFET, however, the polysilicon layer overlapping the thin gate oxide region is formed in a trapezoidal shape layout. Thus, new fabrication techniques are not required to achieve more desirable device characteristics.

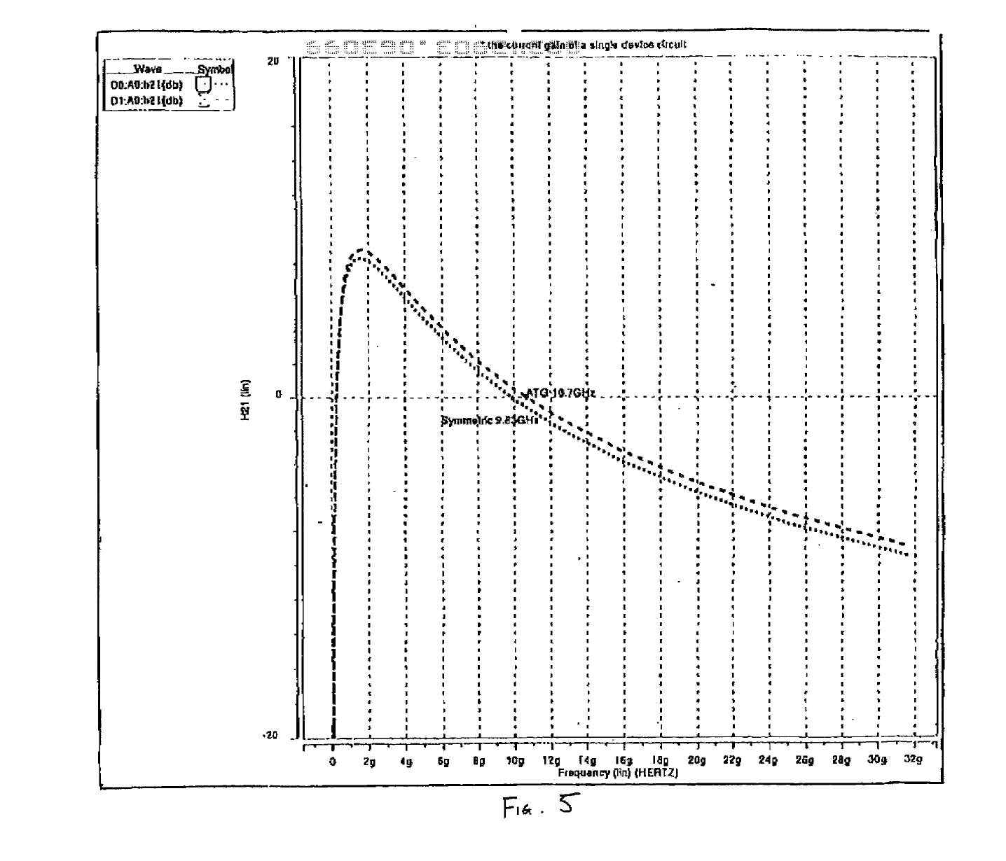

Operation of each RF circuit 100 and 110 was simulated using the same structure with different capacitance parameters with the MOSFET device(s) in each circuit modeled to have characteristics representative of ATG MOSFET 400. Such characteristics were computed from the information in Cho et al. The operation of each circuit 100 and 110 was also simulated with a conventional MOSFET device having a symmetric gate structure. Several conventional MOSFETs of varying size were modeled using the tool “BSIMpro” with BSIM3 v.3 model to provide a benchmark. Next, using an HP8510C meter, the S parameters were measured. This measurement provided the RF characteristics of the MOSFET and accordingly, the possible leakage path which causes the parasitic effects. Results of the simulations are illustrated in FIGS. 5-7.

FIG. 5 is a graphical representation of a unity-current-gain frequency (fₜ) characteristic for RF circuit 100. In FIG. 5 the x-axis represents frequency, while the y-axis depicts the current gain, h21, which is one of the four parameters in a two port network representation of circuit 100. The frequency for h21=0dB defines the unity-current gain frequency (fₜ). As seen in FIG. 5, fₜ has values at 0dB of 9.83 GHz and 10.7 GHz for the symmetric gate and ATG MOSFET implementations, respectively.

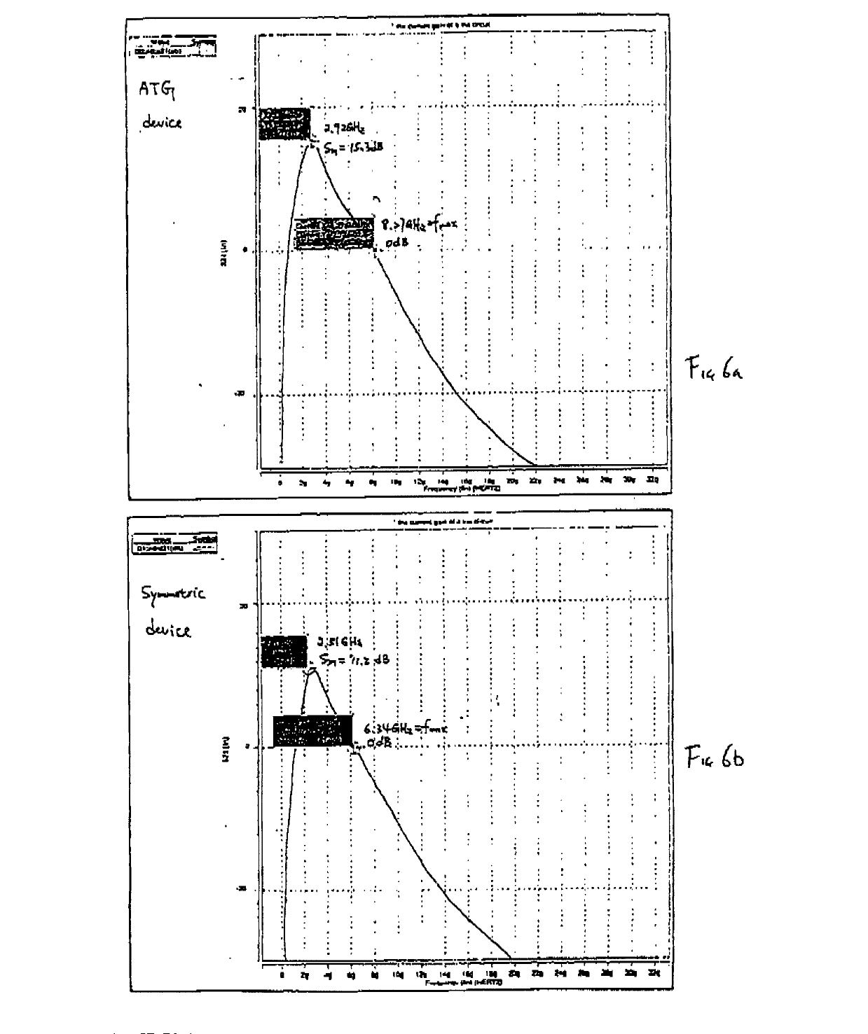

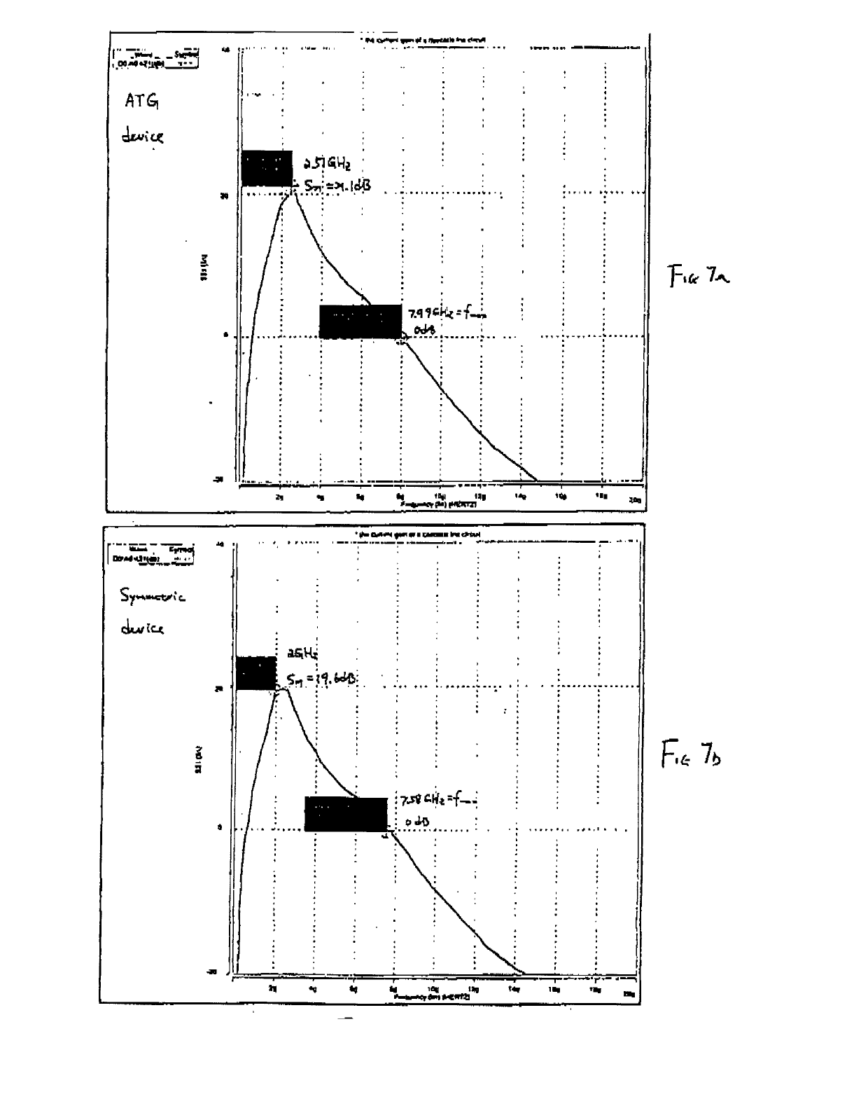

FIGS. 6a and 6b are graphical representations of a unity-power-gain frequency (fₘₐₓ) and f_{t,} for RF circuit 100, with the results for the ATG MOSFET implementation shown in FIG. 6a and the results for the symmetric gate implementation shown in FIG. 6b. FIGS. 7a and 7b are graphical representations of frequencies fₘₐₓ and fₜ for RF circuit 110, with the results for the ATG MOSFET implementation shown in FIG. 7a and the results for the symmetric gate implementation shown in FIG. 7b. In FIGS. 6a, 6b, 7a, and 7b, f_{c} is the carrier frequency. Additionally, FIGS. 6a, 6b, 7a, and 7b depict S21. S21 represents power gain and is one of another set of four parameters in the two port network representation. The frequency of the power gain, for S21=0dB is represented as fₘₐₓ (Unity-power gain frequency).

The two-port network representation of a network and the sets of two-port parameters for the representation are well known. For example, “Microwave Solid-State Circuits and Applications” by K Chang, John Wiley & Sons, 1994, includes a description of two-port networks and is incorporated herein by reference.

The following table summarizes the results illustrated in FIGS. 5, 6a, 6b, 7a, and 7b, where all numerical values are in Ghz.

TABLE

| | |
|---|---|
| Circuit 100 | Circuit 110 |

| | ATG | Symmetric | ATG | Symmetric |
|---|---|---|---|---|
| f_{c} | 2.92 | 2.51 | 2.51 | 2 |
| fₜ | 10.7 | 9.83 | — | — |
| fₘₐₓ | 8.27 | 6.34 | 7.99 | 7.58 |

As demonstrated by the simulation results, the high frequency performance of circuits 100 and 110 is significantly improved by implementing the MOSFETs as the ATG MOSFET described herein. Under the same conditions, the ATG device provides better performance characteristics, in terms of current gain and power gain, than the conventional symmetric MOSFET counterpart device. Therefore, less effort is required to adjust the fabrication process of the circuits.

While the present invention has been illustrated and described including implementation of a multiple finger ATG MOSFET in a high frequency RF circuit, the invention is not so limited. A single element ATG MOSFET such as ATG MOSFET 300 can be successfully implemented in RF circuit applications in which large values of driving current are not required. One example is in a baseband amplifier. By utilizing the ATG MOSFET in the RF circuit, improved performance characteristics are achieved. ATG MOSFETs suppress the Miller effect in both the RF or base-band circuit.

While the present invention has been described in connection with what is considered the most practical and preferred embodiment, it is understood that this invention is not limited to the disclosed embodiment, but is intended to cover various arrangements included within the spirit and scope of the broadest interpretation so as to encompass all such modifications and equivalent arrangements.

What is claimed is:

1. An RF amplifier circuit, comprising:
a MOSFET as an amplifier element, said MOSFET being constructed as an asymmetric trapezoidal gate (ATG) MOSFET.

2. The RF amplifier of claim 1, wherein said MOSFET includes source, gate and drain regions and a width of said source region is greater than a width of said drain region.

3. The RF amplifier of claim 2, wherein the width of said drain region is sufficiently small to reduce a Miller effect capacitance of the MOSFET, further wherein the drain region provides a capacitance C_{GD} in the range of 0.02 fF/μm to 0.5 fF/μm

4. The RF amplifier of claim 3, wherein said gate region tapers at an approximately 45° angle relative to said drain region.

5. The RF amplifier of claim 2, wherein the RF amplifier is configured for amplifying signals having a frequency greater than 800 MHz.

6. The RF amplifier of claim 4, wherein said MOSFET comprises a plurality of said ATG MOSFETs connected in parallel to conduct a required drive current of said RF amplifier.

7. The RF amplifier of claim 6, wherein in each of said plurality of ATG MOSFETs said gate region tapers at an approximately 45° angle relative to said drain region.

8. The RF amplifier of claim 6, wherein the width of said drain region of each of said plurality of ATG MOSFETs is sufficiently small to reduce a Miller effect capacitance of each ATG MOSFET, further wherein the drain region of each device provides a capacitance C_{GD} in the range of 0.02 fF/μm to 0.5 fF/μm

9. The RF amplifier of claim 1, wherein the RF amplifier is configured for amplifying signals having a frequency greater than 800 MHz;
said ATG MOSFET comprising a plurality of ATG MOSFET elements, one of a source and a drain region of each said ATG MOSFET element being shared in common with an adjacent one of said ATG MOSFET elements.

10. The RF amplifier of claim 9, wherein said plurality of ATG MOSFET elements are connected in parallel.

11. The RF amplifier of claim 10, wherein in each of said plurality of ATG MOSFET elements said gate region tapers at an approximately 45° angle relative to said drain region.

12. An ATG MOSFET device, comprising:
a plurality of ATG MOSFET elements each including a gate region, one of a source region and a drain region of each said ATG MOSFET element being shared in common with an adjacent one of said ATG MOSFET elements; and
said plurality of ATG MOSFET elements connected in parallel.

13. The ATG MOSFET device of claim 12, wherein a width of said source region is greater than a width of said drain region.

14. The ATG MOSFET device of claim 13, wherein the width of said drain region is sufficiently small to reduce a Miller effect capacitance of each of said plurality of MOSFET elements, further wherein the drain region of each MOSFET element provides a capacitance C_{GD} in the range of 0.02 fF/μm to 0.5 fF/μm

15. The ATG MOSFET device of claim 12 wherein in each said ATG MOSFET element said gate region tapers at an approximately 45° angle relative to said drain region.

16. The ATG MOSFET device of claim 12, further wherein a driving current capacity is substantially equal to the sum of the individual driving capacities of each ATG MOSFET element of the ATG MOSFET device.

17. The ATG MOSFET device of claim 12, wherein alternate source and drain regions of the adjacent ATG MOSFET elements are commonly shared.
